(19) United States
(12) Patent Application Publication
(10) Pub. No.: US 2026/0076186 A1
(43) Pub. Date: Mar. 12, 2026

(54) POWER SEMICONDUCTOR DEVICES

(71) Applicant: Samsung Electronics Co., Ltd., Suwon-si (KR)

(72) Inventors: Mingu KO, Suwon-si (KR); Taehun KIM, Suwon-si (KR); Younghwan PARK, Suwon-si (KR); Jeonghwan PARK, Suwon-si (KR); Sewoong OH, Suwon-si (KR)

(73) Assignee: Samsung Electronics Co., Ltd., Suwon-si (KR)

(21) Appl. No.: 19/055,217

(22) Filed: Feb. 17, 2025

(30) Foreign Application Priority Data
Sep. 10, 2024 (KR) 10-2024-0123027

(51) Int. Cl. H01L 23/373; H01L 23/00; H01L 25/065; H02M 7/00; H10D 8/01; H10D 8/60; H10D 30/01; H10D 30/66; H10D 62/10; H10D 62/832; H10D 84/01; H10D 84/80; H10D 89/00

(52) U.S. Cl. CPC H10W 40/253; H10D 8/60; H10D 30/66; H10D 30/668; H10D 62/104; H10D 62/8325; H10D 84/811; H10P 58/00; H02M 7/003; H10D 8/051; H10D 30/0291; H10D 84/0107; H10W 72/07554; H10W 72/5453; H10W 72/879; H10W 90/00; H10W 90/724

(57) ABSTRACT

A power semiconductor device includes a substrate including SiC of a first conductivity type and including a first region and a second region, a drift layer of the first conductivity type on the substrate and in the first and second regions, a well region of a second conductivity type on the drift layer and in in the first region, a source region of the first conductivity type within the well region, a gate electrode on and extending along an upper surface of the well region, a source electrode connected to the source region in the first region, a metal layer connected to the drift layer in the second region, and a passivation layer covering the source electrode and the metal layer. The passivation layer defines a recessed portion between the first region and the second region.

### CROSS-REFERENCE TO RELATED APPLICATION(S)

This application claims the benefit under 35 USC 119(a) of Korean Patent Application No. 10-2024-0123027 filed on Sep. 10, 2024 in the Korean Intellectual Property Office, the entire disclosure of which is incorporated herein by reference for all purposes.

### BACKGROUND

The present inventive concepts relate to power semiconductor devices.

Power semiconductor devices are semiconductor devices that operate in relatively high-voltage and relatively high-current environments, and are used in fields desiring high-power switching, such as in power conversion, power converters, and inverters. Power semiconductor devices are fundamentally desired to have relatively high-voltage withstand characteristics, and recently, relatively high-speed switching operations have been additionally desired. Accordingly, power semiconductor devices using SiC, which has relatively good withstand characteristics compared to silicon (Si), are being researched.

### SUMMARY

Some example embodiments provide power semiconductor devices having improved heat dissipation characteristics.

According to an example embodiment, a power semiconductor device includes a substrate including SiC of a first conductivity type, the substrate including a first region and a second region, a drift layer of the first conductivity type on the substrate, the drift layer being in the first region and the second region, a well region of a second conductivity type on the drift layer, the well region being in the first region, a source region of the first conductivity type within the well region, a gate electrode on and extending along an upper surface of the well region, a source electrode connected to the source region in the first region, a metal layer connected t0o the drift layer in the second region, and a passivation layer covering the source electrode and the metal layer. The passivation layer defines a recessed portion between the first region and the second region.

According to an example embodiment, a power semiconductor device includes a first region including a transistor, a second region spaced apart from the first region, the second region including a Schottky barrier diode, a passivation layer on the first region and the second region, and a third region between the first region and the second region, the third region being a region in which at least a portion of the passivation layer is removed. The first region includes a first SiC substrate of a first conductivity type, a well region of a second conductivity type on the first SiC substrate, a source region of the first conductivity type within the well region, a gate electrode on an upper surface of the well region, and a source electrode connected to the source region. The second region includes a second SiC substrate of the first conductivity type, and an electrode layer connected to the second SiC substrate. The first SiC substrate and the second SiC substrate are respective parts of an integral body.

According to an example embodiment, a power semiconductor device includes a substrate including SiC of a first conductivity type, the substrate including a first region and a second region, a well region of a second conductivity type on the substrate, the well region being in the first region, a source region of the first conductivity type within the well region, a gate electrode on and extending along an upper surface of the well region, a source electrode connected to the source region in the first region, a metal layer connected to the substrate in the second region, a passivation layer covering the source electrode and the metal layer, the passivation layer including a first pad region and a second pad region, the first pad region exposing at least a portion of the source electrode, the second pad region exposing at least a portion of the metal layer, and a connecting member electrically connecting the source electrode exposed in the first pad region and the metal layer exposed in the second pad region. The passivation layer defines a recessed portion between the first region and the second region, and the recessed portion defines a scribe lane.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1 is a circuit diagram of a power semiconductor device according to an example embodiment;

FIG. 2 is a schematic plan view of a power semiconductor device according to an example embodiment;

FIG. 3 is a schematic cross-sectional view of a power semiconductor device an according to an example embodiment;

FIG. 4 is a cross-sectional view of a power semiconductor device according to an example embodiment;

FIG. 5 is a plan view of a power semiconductor device according to an example embodiment;

FIG. 6 is a cross-sectional view of a power semiconductor device according to an example embodiment;

FIG. 7 is a cross-sectional view of a power semiconductor device according to an example embodiment;

FIG. 8 is a cross-sectional view of a power semiconductor device according to an example embodiment;

FIGS. 9 to 12 are drawings illustrating a method of manufacturing a power semiconductor device according to an example embodiment;

FIG. 13 is a circuit diagram illustrating a power unit to which a power semiconductor device according to an example embodiment is applied;

FIG. 14 is a configuration diagram of a semiconductor package illustrating an inverter module of FIG. 13; and

FIG. 15 is a cross-sectional view of a semiconductor package illustrating an inverter module of FIG. 14.

### DETAILED DESCRIPTION

Hereinafter, example embodiments will be described with reference to the attached drawings. Terms such as “on,” “upper portion,” “upper surface,” “below,” “lower portion,” “lower surface,” “side,” “side surface,” and the like can be understood to refer to the drawings, unless otherwise explained.

As used herein, expressions such as “one of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

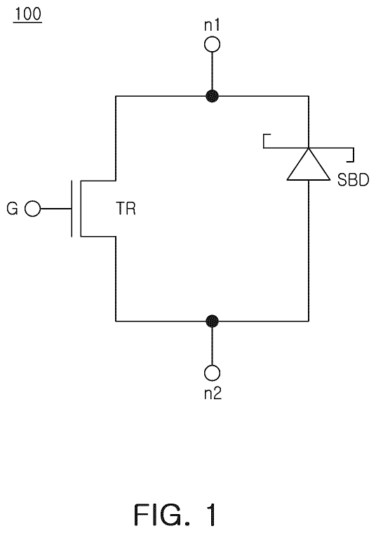

FIG. 1 is a circuit diagram of a power semiconductor device according to an example embodiment.

A power semiconductor device 100 according to an example embodiment is a semiconductor device 100 applied to an inverter circuit, and may include a diode (SBD) connected to a transistor (TR) in parallel.

The transistor (TR) is a power element, and includes a gate (G), a source(S), and a drain (D), and the drain (D) may be connected to a first node n1 and the source(S) may be connected to a second node n2. The transistor (TR) may be turned on or off according to an on a signal of the gate (G), and may transmit a positive voltage from a direct current power source of the first node n1 to a target object through the second node n2 during the turn-on time. The diode (SBD) connected to the transistor (TR) in parallel may be a rectifier diode (SBD) and may be connected in the reverse direction to a direct current power source. For example, the cathode may be connected to the first node n1 to which a positive voltage is applied, and the anode may be connected to the second node n2.

In general operation, when a positive voltage is applied to the first node n1 from a DC power source, the diode (SBD) is turned off, and current may flow toward the transistor (TR). When the transistor (TR) is turned off, and when a negative voltage is applied to the first node n1, the diode (SBD) is forward biased, so that the diode (SBD) is turned on, and current may flow toward (e.g., on a side of) the diode (SBD). The diode (SBD) may be a Schottky Barrier Diode (SBD) and may be formed on the same SiC substrate as the transistor (TR).

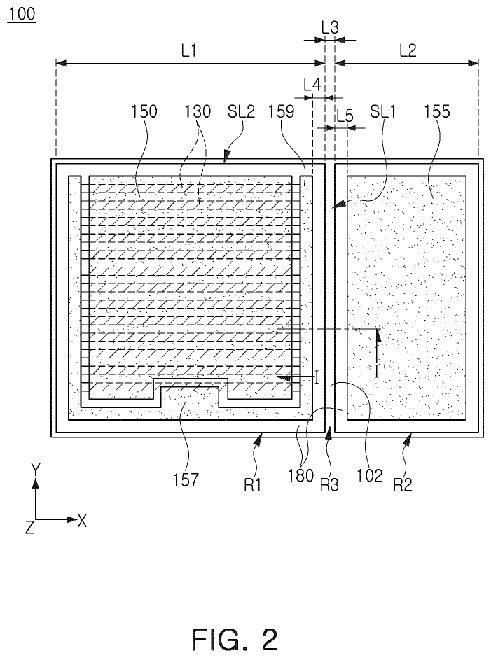

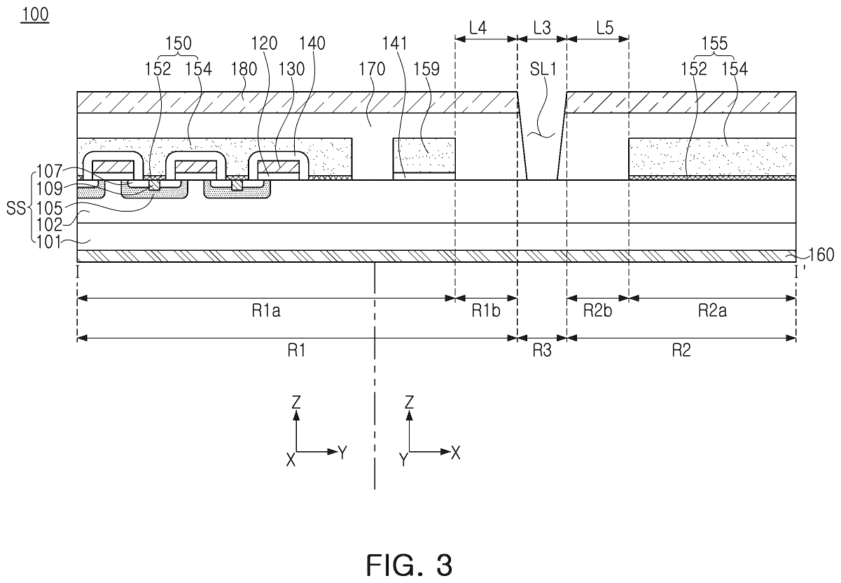

FIG. 2 is a schematic plan view of a power semiconductor device according to an example embodiment, and FIG. 3 is a schematic cross-sectional view of a power semiconductor device according to an example embodiment. FIG. 3 illustrates a cross-section taken along line I-I′ of FIG. 2.

Referring to FIGS. 2 and 3, a power semiconductor device 100 may include a first region R1, a second region R2, and a third region R3 as scribe lanes SL1 and SL2 surrounding the first region R1 and the second region R2, on a substrate 101. The first region R1 may include a first type circuit element, and the first type circuit element may be a transistor (TR). The second region R2 may be disposed adjacent to the first region R1 in the X-direction, and may be disposed spaced apart from the first region R1 in the X-direction. The second region R2 may include a second type circuit element, and the second circuit element may be a diode (SBD), for example, a Schottky barrier diode (SBD). Hereinafter, a substrate structure (SS) may also be understood to include a first region R1, a second region R2, and a third region R3 corresponding to the first region R1, the second region R2, and the third region R3.

The first region R1 may include a first element region R1a and a first edge region R1b. The first element region R1a may be surrounded by the first edge region R1b and may be defined as a substantially active region in which a first type circuit element is disposed. The first edge region R1b may surround the first element region R1a and have a frame shape, and may be defined as a region in which no metal layer is disposed within the first region R1.

The second region R2 may include a second element region R2a and a second edge region R2b. The second element region R2a may be surrounded by the second edge region R2b and may be defined as a substantial active region in which a second type circuit element is disposed. The second edge region R2b may surround the second element region R2a and have a frame shape, and may be defined as a region in which a metal layer is not disposed within the second region R2.

The first region R1 may have a larger area than the second region R2. In the XY plane, when the first region R1 and the second region R2 have the same length in the Y-direction, the difference in the area between the first region R1 and the second region R2 may be due to the difference in the lengths L1 and L2 of the first region R1 and the second region R2 in the X-direction. The widths L4 and L5 of the first edge region R1b and the second edge region R2b (e.g., the widths L4 and L5 of the frame in the X-direction or the Y-direction) may be substantially the same. The first length L1 of the first region R1 may be greater than the second length L2 of the second region R2, and for example, the first length L1 may be about 3 to about 5 times (e.g., about 4 times) the second length L2, but is not limited thereto.

The first width L4 of the first edge region R1b may be smaller than the second length L2, and the second width L5 of the second edge region R2b may be smaller than the second length L2. For example, the first region R1 may be a quadrilateral, for example, a square, and may have an area of about 3 mm *3 mm, and the second region R2 may be a quadrilateral, for example, a rectangle, and may have an area of about 0.75 mm *3 mm, but is not limited thereto. The first width L4 and the second width L5 may have a length of about 100 μm to 160 μm, but are not limited thereto.

A scribe lane SL1 may be disposed in a third region R3 between the first region R1 and the second region R2. The scribe lane SL1 may be a line type extending in the Y-direction between the first region R1 and the second region R2. The scribe lane SL1 may be defined as a recessed region in which the upper surface thereof is recessed to approach the substrate 101 between the first region R1 and the second region R2, and as an example, may be a recessed region that is sunken so that t3he substrate 101 is exposed. The scribe lane SL1 may have a third width L3 in the X-direction. The third width L3 may be equal to or smaller than the first width L4 and/or the second width L5, and as an example, may be about 100 μm, but is not limited thereto.

The scribe lanes SL1 and SL2 may include a peripheral scribe lane SL2 surrounding the edges of the first region R1 and the second region R2 in addition to the scribe lane SL1 between the first region R1 and the second region R2. The peripheral scribe lane SL2 surrounding the first region R1 and the second region R2 may have a smaller width than the scribe lane SL1 between the first region R1 and the second region R2.

The first region R1 may be a region where a transistor (TR) is disposed as a first type circuit element.

The first region R1 may include a substrate structure (SS), gate electrodes 130 on the substrate structure (SS), gate insulating layers 120 between the gate electrodes 130 and the substrate structure (SS), dielectric layers 140 covering the gate electrodes 130, a source electrode 150 on the dielectric layers 140, a back electrode 160 on the lower surface of the substrate 101, and first and second passivation layers 170 and 180 on the source electrode 150.

The substrate structure (SS) may include a substrate 101, a drift layer 102 on the substrate 101, well regions 105 extending from the upper surface of the drift layer 102, source regions 107 extending from the upper surfaces of the well regions 105 in the respective well regions 105, and well contact regions 109 on one sides of the source regions 107.

The substrate 101 may have an upper surface extending in the X-direction and the Y-direction. The substrate 101 may include a semiconductor material, for example, SiC. However, in some example embodiments, the substrate 101 may also include a group IV semiconductor material such as Si or Ge, or a compound semiconductor material such as SiGe, GaAs, InAs, or InP.

The substrate 101 may be provided as a bulk wafer or an epitaxial layer. The substrate 101 may include first conductivity type impurities and thus may have a first conductivity type. In some example embodiments, the first conductivity type may be, for example, N-type, and the first conductivity type impurities may be N-type impurities, such as, for example, nitrogen (N) and/or phosphorus (P). In some example embodiments, the first conductivity type may be, for example, P-type, and the first conductivity type impurities may be P-type impurities, such as, for example, aluminum (Al).

The drift layer 102 may be disposed on the substrate 101. The drift layer 102 may include a semiconductor material, for example, may include SiC. The drift layer 102 may be an epitaxial layer grown on the substrate 101. The drift layer 102 may include first conductivity-type impurities, and thus may have the first conductivity type. The concentration of the first conductivity-type impurities of the drift layer 102 may be lower than the concentration of the first conductivity-type impurities of the substrate 101. In same example embodiments, the first conductivity-type impurities in the substrate 101 and the drift layer 102 may be the same or different from each other.

The substrate 101 and the drift layer 102 of the first region R1 may be disposed continuously from the first region R1 to the second region R2, and may form an integrated substrate 101 and an integrated drift layer 102 for the two element regions R1a, R2a.

In the first region R1, the well regions 105 may be disposed at a desired (or alternatively, predetermined) depth from the upper surface of the drift layer 102, and may be disposed to be spaced apart from each other in the horizontal direction, for example, the Y-direction. The well region 105 may include a semiconductor material, for example, may include SiC. The well region 105 may be a region having a second conductivity type, and may include second conductivity type impurities. The second conductivity type may be, for example, P type, and the second conductivity type impurities may be, for example, P type impurities such as aluminum (Al). In some example embodiments, the well region 105 may include a plurality of regions having different doping concentrations.

The source regions 107 may be disposed at a desired (or alternatively, predetermined) depth from the upper surfaces of the well regions 105. The source region 107 may include a semiconductor material, for example, SiC. The source region 107 may be a region having the first conductivity type and may include the first conductivity type impurities described above. The concentration of the first conductivity type impurities in the source region 107 may be higher than the concentration of the first conductivity type impurities in the drift layer 102, but is not limited thereto.

The well contact regions 109 may be disposed on the well regions 105, on at least one side of some of the source regions 107. The well contact region 109 may be disposed between the well region 105 and the source electrode 150 so that a voltage from the source electrode 150 may be applied to the well region 105. In some example embodiments, the relative depths of the well contact region 109 and the source region 107 may vary. The well contact region 109 may include a semiconductor material, for example, SiC. The well contact region 109 may be a region having the second conductivity type and may include the second conductivity type impurities described above. The concentration of the second conductivity type impurities in the well contact region 109 may be higher than the concentration of the second conductivity type impurities in the well region 105.

In the first element region R1a of the first region R1, gate electrodes 130 are disposed on the substrate structure (SS), and may be disposed on one end of the source regions 107 and the well regions 105 outside the source regions 107. The gate electrode 130 may be disposed to overlap a portion of the source region 107 and a portion of the well region 105 in a vertical direction, for example, in the Z-direction. The gate electrode 130 may be separated from the source region 107, the well region 105, and the drift layer 102 by a gate insulating layer 120.

The gate electrode 130 may include a conductive material, and may include, for example, a semiconductor material such as doped polycrystalline silicon, metal nitride such as titanium nitride (TiN), tantalum nitride (TaN), or tungsten nitride (WN), and/or a metal material such as aluminum (Al), tungsten (W), or molybdenum (Mo). In some example embodiments, the gate electrode 130 may be a multilayer structure composed of two or more layers. The gate electrodes 130 are disposed on the substrate structure (SS) and may extend along the upper surface of the well region 105 forming the upper surface of the substrate structure (SS). The gate electrodes 130 may have a shape corresponding to the shape of the upper surface of the well region 105 on a plane, and may have, for example, a line shape. The gate electrodes 130 may have line shapes that are spaced apart from each other in the Y-direction and extend in the X-direction, and may be disposed in parallel.

The gate insulating layers 120 may be disposed on the lower surfaces of the gate electrodes 130. The gate insulating layer 120 may extend over the source region 107, the well region 105 outside the source region 107, and the drift layer 102. The gate insulating layer 120 may be disposed between the source region 107 and the gate electrode 130, between the well region 105 and the gate electrode 130, and between the drift layer 102 and the gate electrode 130.

The gate insulating layer 120 may include oxide, nitride, or a high-κ material. The high-κ material may mean a dielectric material having a higher dielectric constant than silicon oxide (SiO₂). The high-κ material may be, for example, one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), or praseodymium oxide (Pr₂O₃). In some example embodiments, the gate insulating layer 120 may be a multilayer structure composed of two or more layers.

The dielectric layers 140 may cover the gate electrodes 130 and may be disposed to expose respective at least portions of the source regions 107 and the well contact regions 109. The dielectric layer 140 may cover the side surface of the gate electrode 130 and the side surface of the gate insulating layer 120. In some example embodiments, the dielectric layers 140 may be disposed on the substrate structure (SS) outside the source electrodes 150 and may insulate the gate bus lines 159 passing therethrough from the substrate structure (SS). The dielectric layer 140 may include an insulating material and may include at least one of silicon oxide, silicon nitride, or silicon oxynitride. In some embodiments, the dielectric layer 140 may include a high-κ material.

In the first element region R1a of the first region R1, the source electrode 150 may be disposed on the dielectric layer 140 and electrically connected to the source regions 107 and the well contact regions 109. The source electrode 150 may have an upper surface of a plate shape to cover most of the area of the first element region R1a, and may have a portion of a lower surface protruding in the Z-direction between the gate electrodes 130 to contact the source regions 107 and the well contact regions 109. The source electrode 150 may include a metal-semiconductor compound layer 152 disposed at an interface contacting the source regions 107 and the well contact regions 109, and a conductive layer 154 on the metal-semiconductor compound layer 152. The metal-semiconductor compound layer 152 may include a metal element and a semiconductor element, and may include, for example, at least one of TiSi, CoSi, MoSi, LaSi, NiSi, TaSi, or WSi. The conductive layer 154 may include a metal material, for example, at least one of nickel (Ni), aluminum (Al), titanium (Ti), silver (Ag), vanadium (V), tungsten (W), cobalt (Co), molybdenum (Mo), copper (Cu), or ruthenium (Ru).

The back electrode 160 may be disposed on the back surface of the substrate 101 and may be electrically connected to the substrate 101. The back electrode 160 may be disposed entirely on the back surface of the substrate 101, but is not limited thereto, and may be patterned in various forms.

A region of the back electrode 160 disposed in the first element region R1a may be defined as a drain electrode, and may be an electrode that flows a drain current to the substrate 101, which is a drain of a transistor formed in the first element region R1a. The back electrode 160 may include a metal material, for example, at least one of nickel (Ni), aluminum (Al), titanium (Ti), silver (Ag), vanadium (V), or tungsten (W). In some example embodiments, the back electrode 160 may also include a metal-semiconductor compound layer similar to the source electrode 150.

Meanwhile, as illustrated in FIG. 2, the gate pad 157 and gate bus lines 159 in the first region R1 may be electrically and physically connected to a plurality of gate electrodes 130 at the same time, and may be a gate wiring structure for connecting the gate electrodes 130 to the outside.

The gate pad 157 is disposed on one sides of the gate electrodes 130 and may be electrically connected to the gate electrodes 130 through the gate bus lines 159. The gate pad 157 may be electrically connected to a separate pad metal layer disposed on the upper side, and may receive an electrical signal through the pad metal layer. In some example embodiments, some of the gate electrodes 130 may extend below the gate pad 157 and may be vertically connected to the gate pad 157. The gate pad 157 may have a shape such as a quadrangle, a circle, or an oval in a plan view, depending on some example embodiments.

The gate bus lines 159 may be disposed in multiple numbers, for example, two, and may be connected to one end and the other end of the gate electrodes 130, respectively. The gate bus lines 159 may be disposed in a symmetrical form centered on or with respect to the gate pad 157.

The gate bus line 159 may include a first bus region connected to the gate pad 157 and extending in the X-direction from the gate pad 157, and a second bus region extending from both ends of the first bus region in a direction intersecting the extension direction of the gate electrodes 130, for example, in the Y-direction. The gate bus line 159 may be disposed on a plurality of gate electrodes 130, as illustrated in FIG. 2. The gate bus line 159 may penetrate the dielectric layer 140 in at least one area and be vertically connected to the gate electrode 130 therebelow. The gate bus line 159 may have a uniform width and may be extended, but in some example embodiments, the width of the gate bus line 159 may increase as moving away from the gate pad 157. The gate pad 157 and the gate bus lines 159 may include a conductive material, for example, a metal material. The gate pad 157 and the gate bus lines 159 may include a material that is the same as or different from the conductive layer 154 of the source electrode 150. The gate pad 157 and the gate bus lines 159 may include, for example, a metal material, for example, at least one of nickel (Ni), aluminum (Al), titanium (Ti), silver (Ag), vanadium (V), tungsten (W), cobalt (Co), molybdenum (Mo), copper (Cu), or ruthenium (Ru). A bus insulating layer 141 may be further disposed between the gate pad 157 and the gate bus lines 159 and the upper surface of the substrate structure (SS). The bus insulating layer 141 may include the same material as the dielectric layer 140, but is not limited thereto.

The first and second passivation layers 170 and 180 may be sequentially laminated on the source electrode 150 and the dielectric layer 140. The first passivation layer 170 may include an insulating material, and may include at least one of silicon oxide, silicon nitride, or silicon oxynitride. The second passivation layer 180 may include an insulating material, for example, photosensitive polyimide (PSPI).

For example, the first and second passivation layers 170 and 180 may be sequentially laminated on the upper surface of the substrate structure (SS) outside the gate bus lines 159, for example, in the first edge region R1a, to protect the first type circuit element from the outside.

The first type circuit element in the first region R1 of the semiconductor device 100 is described as an example of a Metal Oxide Semiconductor Field Effect Transistor (MOSFET), but the gate insulating layer 120 of the example embodiments may also be applied to a super junction MOSFET, a double trench MOSFET, an Insulated Gate Bipolar Transistor (IGBT) element, or the like. For example, when the power semiconductor element is an IGBT, the substrate 101 may have the second conductivity type.

Meanwhile, the semiconductor device 100 may include a second region R2 spaced apart from the first region R1 by a third width L3 in the X-direction. The second region R2 includes a second type circuit element, and the second type circuit element may be a Schottky barrier diode (SBD).

A substrate 101 and a drift layer 102 are disposed in the second region R2, and a metal layer 155 in contact with the drift layer 102 may be disposed.

In the second region R2, the substrate 101 may be integrated with the substrate 101 of the first region R1, and it may be understood that the substrate 101 of the first region R1 is extended to and disposed on the second region R2. Accordingly, a part of the integrated substrate 101 may be utilized as a drain in the first region R1, and another part may be utilized as a cathode in the second region R2.

In the second region R2, the substrate 101 may have an upper surface extending in the X-direction and the Y-direction, as described above. The substrate 101 may include a semiconductor material, for example, may include SiC. However, in some example embodiments, the substrate 101 may include a group IV semiconductor material such as Si or Ge, or a compound semiconductor material such as SiGe, GaAs, InAs, or InP.

The substrate 101 may be provided as a bulk wafer or an epitaxial layer. The substrate 101 may include first conductivity-type impurities, and thus may have a first conductivity type. In some example embodiments, the first conductivity type may be, for example, N-type, and the first conductivity-type impurities may be, for example, N-type impurities, such as nitrogen (N) and/or phosphorus (P). In some example embodiments, the first conductivity type may be, for example, P-type, and the first conductivity-type impurities may be, for example, P-type impurities, such as aluminum (Al).

The drift layer 102 extends from the drift layer 102 of the first region R1 and may be disposed on the substrate 101. The drift layer 102 may include a semiconductor material, for example, may include SiC. The drift layer 102 may be an epitaxial layer grown on the substrate 101. The drift layer 102 may include first conductivity-type impurities, and thus may have the first conductivity type. The concentration of the first conductivity-type impurities of the drift layer 102 may be lower than the concentration of the first conductivity-type impurities of the substrate 101. In some example embodiments, the first conductivity-type impurities in the substrate 101 and the drift layer 102 may include the same or different elements.

The second region R2 may not include a separate well region and/or source region, and may include a metal layer 155 in direct contact with the drift layer 102.

The metal layer 155 may have the same layer structure as the source electrode 150 of the first region R1 and may include the same metal material. Therefore, the metal layer 155 may have the same height as the source electrode 150. The metal layer 155 may form a Schottky contact during metal-semiconductor junction with the drift layer 102.

The metal layer 155 may have a plate type to cover most of the area of the second element region R2a, and the lower surface may be in contact with the drift layer 105. The metal layer 155 may include a metal-semiconductor compound layer 152 disposed at an interface in contact with the drift layer 105, but is not limited thereto. The metal layer 155 may include a conductive layer 154 on the metal-semiconductor compound layer 152. The metal-semiconductor compound layer 152 may include a metal element and a semiconductor element, and may include at least one of TiSi, CoSi, MoSi, LaSi, NiSi, TaSi, or WSi, for example. The conductive layer 154 may include a metal material, for example, at least one of nickel (Ni), aluminum (Al), titanium (Ti), silver (Ag), vanadium (V), tungsten (W), cobalt (Co), molybdenum (Mo), copper (Cu), or ruthenium (Ru).

The back electrode 160 may also be disposed on the back surface of the substrate 101 of the second region R2 and may be electrically connected to the substrate 101. The back electrode 160 may extend continuously from the first region R1 to the second region R2. In some example embodiments, the back electrode 160 may be patterned only in a portion of the region to apply a cathode voltage to the substrate 101. The drain voltage applied to the drain of the first type circuit element may be the voltage applied to the cathode, which is the semiconductor substrate 101, in the second type circuit element.

The first and second passivation layers 170 and 180 may be sequentially laminated on the metal layer 155. The first passivation layer 170 may include an insulating material, and may include at least one of silicon oxide, silicon nitride, or silicon oxynitride. The second passivation layer 180 may include an insulating material, for example, photosensitive polyimide (PSPI).

For example, the first and second passivation layers 170 and 180 may be sequentially laminated from the upper surface of the drift layer 102 on the outside of the metal layer 155, for example, the second edge region R2b, to protect the second type circuit element from the outside.

The first and second passivation layers 170 and 180 may include the same materials in the first region R1 and the second region R2, but may not be physically connected. For example, the second passivation layer 180 may be physically separated by the recessed region of the scribe lane SL1 between the first region R1 and the second region R2.

In this manner, the first region R1 and the second region R2 are included on one substrate 101, and a power transistor (TR) is disposed in the first region R1, and a Schottky barrier diode (SBD) is disposed in the second region R2, so that heat generated from the power transistor (TR) handling a relatively high voltage and a relatively high current may be transferred to the substrate 101 of the second region R2 along the substrate 101. Therefore, heat dissipation efficiency may be improved by a large area semiconductor substrate 101 by processing heat generation of a transistor (TR) through a substrate 101 of a diode (SBD) with relatively low heat generation.

A scribe lane SL1 may be disposed between the first region R1 and the second region R2 as illustrated in FIG. 2, and the scribe lane SL1 has a third width L3 in the X-direction and may be a recessed region in which both the first passivation layer 170 and the second passivation layer 180 are removed so that the upper surface of the substrate 101 is exposed. According to an example embodiment, the recessed region may be formed such that at least a part of the first passivation layer 170 remains on the substrate structure (SS), but is not limited thereto.

The recessed region forming the scribe lane SL1 may be disposed such that the side surface of the first region R1 and the side surface of the second region R2 face each other and the two side surfaces are inclined from the upper surface of the substrate 101. In this case, the third width L3 of the scribe lane SL1 refers to the width of the upper end thereof, and the width of the lower end of the scribe lane SL1 (e.g., the width of the exposed substrate 101 in the X-direction in the recessed region forming the scribe lane SL1) may be smaller than the third width L3. For example, the width of the recessed region of the scribe lane SL1 may decrease as it goes downward (e.g., as being closer to the exposed substrate 101), and accordingly, the two opposing side surfaces each may have an incline, but the present inventive concepts are not limited thereto. In some example embodiments, The two opposing side surfaces forming the recessed region of the scribe lane SL1 may be disposed perpendicularly to the upper surface of the substrate 101.

Based on the scribe lane SL1, the first region R1 and the second region R2 may be disposed on both sides in the X-direction, and based on the scribe lane SL1, the first edge region R1b of the first region R1 and the second edge region R2b of the second region R2 may be disposed on both sides in the X-direction. Accordingly, the first element region R1a and the second element region R2a may be disposed spaced apart from each other.

The semiconductor device 100 may be formed and disposed with a transistor (TR) and a Schottky barrier diode (SBD) together while sharing a single substrate 101, and may be cut along a scribe lane SL1 according to the circuit design to form two independent elements.

However, as in FIG. 1, in the case of a rectifier circuit applied to an inverter circuit, because a diode (SBD) connected to one power transistor (TR) in parallel is desired, the semiconductor device 100 of FIGS. 2 and 3 may be implemented as one chip. As in FIG. 1, when the semiconductor device 100 implements one rectifier circuit, the source electrode 150 of the first region R1 and the metal layer 155 of the second region R2 may be electrically connected through a connecting member, for example, a wire, so that they are simultaneously connected to the second node n2.

In addition, the drain electrode of the first region R1 and the cathode electrode of the second region R2 may be integrated with the back electrode 160 and disposed as illustrated in FIG. 2, to be simultaneously connected to the first node n1.

In the case where a connecting member connecting the source electrode 150 and the metal layer 155 is disposed at the top, it may be directly applied to the inverter circuit of FIG. 1, and depending on the magnitude of the voltage applied to the first node n1 and the second node n2, the Schottky barrier diode (SBD) may be turned on or maintained in a turn-off state. Only when the turn-on voltage is applied to the gate electrode of the power transistor (TR) in the normal state where the Schottky barrier diode (SBD) is turned off, an AC current may be selectively passed through the drain.

The semiconductor device 100 may further include a scribe lane SL1 between the first region R1 and the second region R2, as well as a peripheral scribe lane SL2 disposed to surround the first region R1 and the second region R2, which may mean that the first region R1 and the second region R2 are cut off. Accordingly, the width of the peripheral scribe lane SL2 may be smaller than the width of the scribe lane SL1 of the third region R3, and may be, for example, about half the width of the scribe lane SL1, but is not limited thereto.

In the description of the example embodiments below, any description overlapping with the description described above with reference to FIGS. 1 and 3 will be omitted.

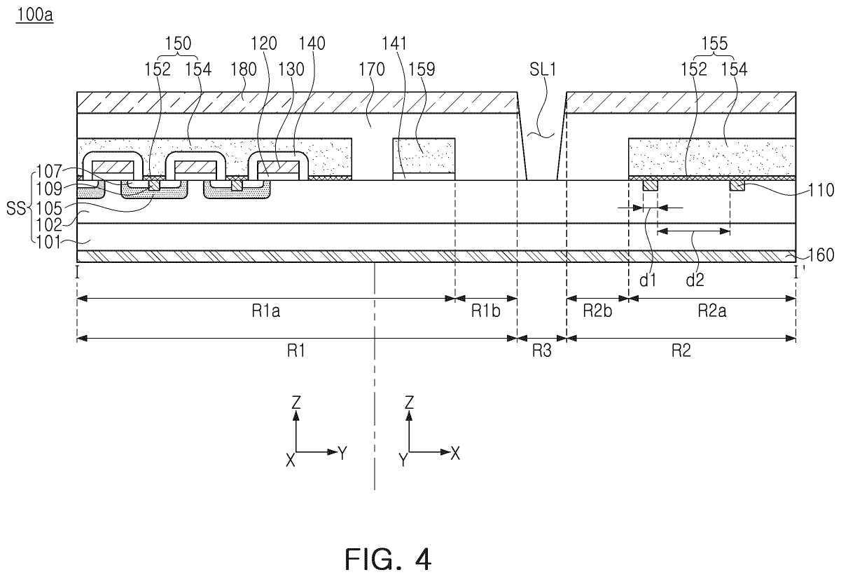

FIG. 4 is a cross-sectional view illustrating a power semiconductor device according to an example embodiment.

Referring to FIG. 4, in a semiconductor device 100a, a Schottky barrier diode (SBD), which is a second type circuit element, may further include junction barrier regions 110 between the metal layer 155 and the drift layer 102 of the substrate 101.

The junction barrier regions 110 may be disposed at a desired (or alternatively, predetermined) depth on the upper surface of the substrate 101, for example, on the upper surface of the drift layer 102, and when the drift layer 102 is doped with an N-type impurity, the junction barrier regions 110 may be doped with an opposite P-type impurity.

The junction barrier regions 110 induce the drift layer 102 including the N-type impurity to form a PN junction, and the drift layer 102 may form a Schottky barrier junction with the metal layer 155, and may form a PN junction with the junction barrier regions 110, and the Schottky barrier diode may be a junction barrier Schottky diode. By arranging the PN junction between the Schottky barrier junctions, reverse current may be reduced or prevented. The junction barrier regions 110 are formed to have a pattern width d1 in a desired (or alternatively, predetermined) direction, for example, an X-direction, and a separation distance between adjacent junction barrier regions 110 may satisfy a first separation distance d2 greater than the pattern width d1.

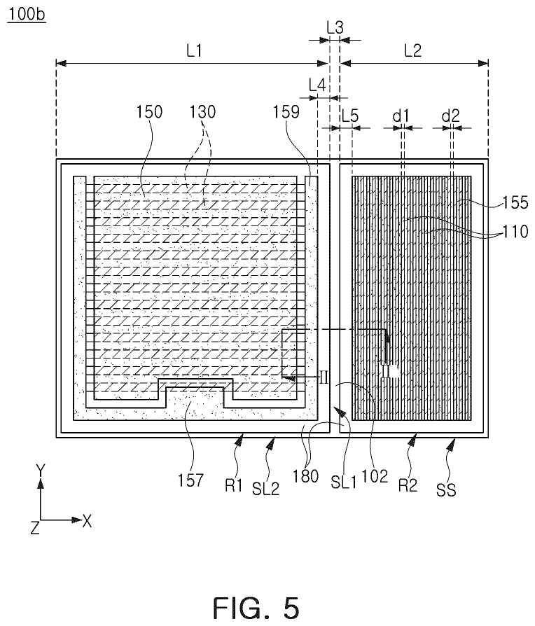

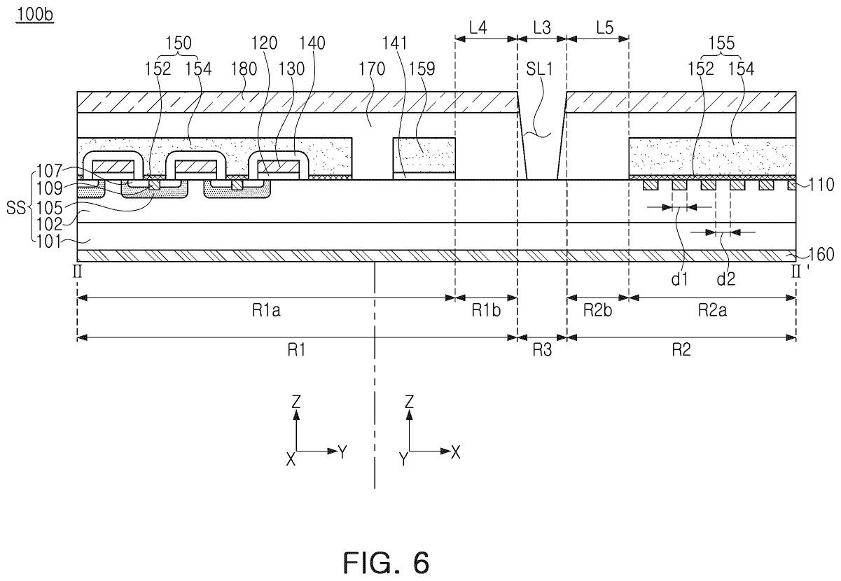

FIG. 5 is a cross-sectional view illustrating a power semiconductor device according to an example embodiment, and FIG. 6 is a cross-sectional view of the semiconductor device of FIG. 5 taken along line II-II′.

Referring to FIG. 5 and FIG. 6, in a semiconductor device 100b, a Schottky barrier diode (SBD), which is a second type circuit element, may further include junction barrier regions 110 between the metal layer 155 and the drift layer 102 of the substrate 101.

The junction barrier regions 110 may be disposed at a desired (or alternatively, predetermined) depth on the upper surface of the substrate 101, for example, on the upper surface of the drift layer 102, and when the drift layer 102 is doped with an N-type impurity, the junction barrier regions 110 may be doped with an opposite P-type impurity.

The junction barrier regions 110 are induced to form a PN junction with the drift layers 102 including the N-type impurity, and the drift layers 102 may form a Schottky barrier junction with the metal layers 155, and a PN junction with the junction barrier regions 110. At this time, the junction barrier regions 110 may be doped in a line type extending in the Y-direction on the XY plane of the drift layer 102, as illustrated in FIG. 5, and may be disposed to have a second separation distance d2 with the neighboring junction barrier regions 110.

At this time, the X-direction pattern width d1 of each of the junction barrier regions 110 may be equal to or greater than the second separation distance d2, which is the separation distance between the neighboring junction barrier regions 110.

Therefore, in the entire diode (SBD) area, the area forming the Schottky barrier junction may be equal to or smaller than the area forming the PN junction. In this case, when the area forming the PN junction is very large, it has a Merged PN Schottky (MPS) structure, and the resistance of the drift layer 102 may be lowered by increasing the current through the PN junction, thereby reducing the leakage current.

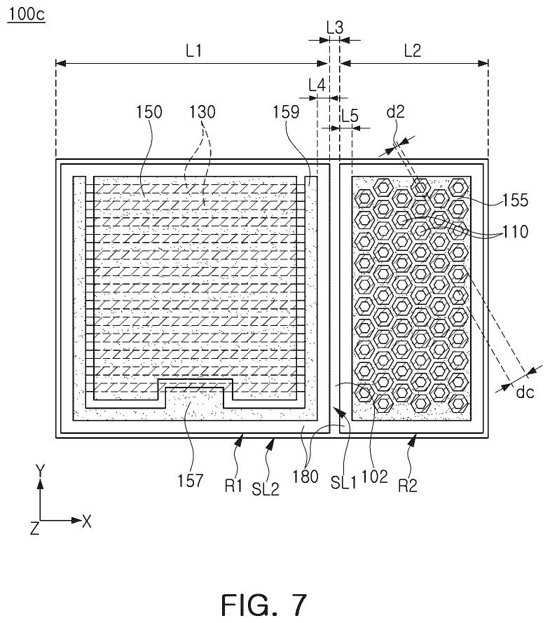

FIG. 7 is a cross-sectional view illustrating a semiconductor device according to an example embodiment.

Referring to FIG. 7, in a semiconductor device 100c of FIGS. 5 and 6, the Schottky barrier diode (SBD), which is a second type circuit element, may further include junction barrier regions 110 between the metal layer 155 and the drift layer 102 on the substrate 101.

The junction barrier regions 110 may be implemented as a ring shape, circle, polygon, or the like, surrounding the Schottky junction region, as illustrated in FIG. 7, and the metal layer 155 inside the junction barrier regions 110 contacts the drift layer 102, and the metal layer 155 outside the junction barrier regions 110 contacts the drift layer 102, thereby shielding the electric field of the Schottky junction regions inside. The maximum diameter dc of respective junction barrier regions 110 may be larger than the separation distance d2, but the total area thereof may be similar to that in FIG. 5 in that the Schottky junction region is disposed inside of a corresponding junction barrier regions 110.

In this manner, the diode (SBD), which is a second type circuit element, may be implemented as a Schottky barrier diode (SBD) in various ways.

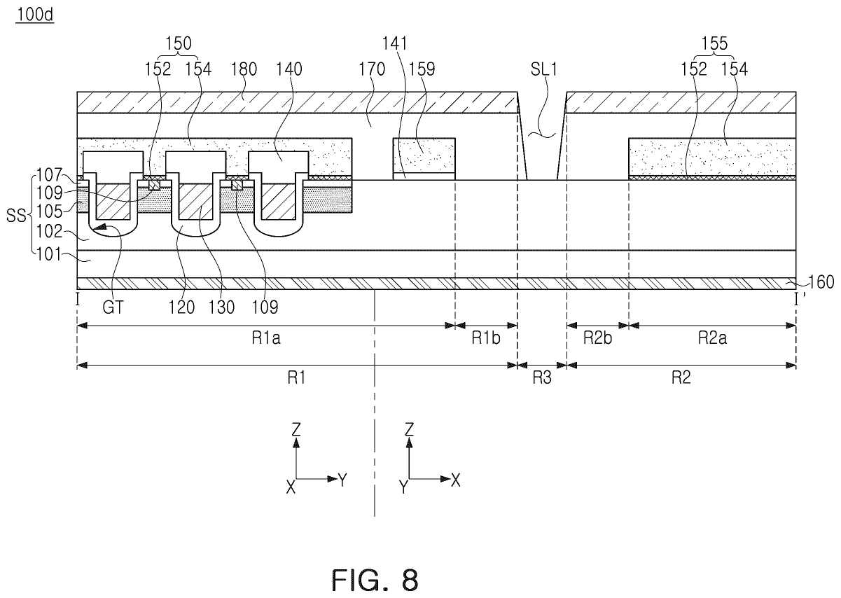

Meanwhile, a semiconductor device 100d of FIG. 8 may be the same as FIG. 2 and FIG. 3 except for the shape of the transistor (TR) of the first region R1.

The semiconductor device 100d of FIG. 8 may include a buried gate electrode 130 in the first region R1.

Referring to FIG. 8, in the semiconductor device 100d, unlike the example embodiment of FIG. 2, the gate insulating layers 120 and the gate electrodes 130 may be disposed within the gate trenches (GT).

The gate trenches (GT) may extend from the upper surfaces of the source regions 107 and penetrate through the source regions 107 and the well regions 105 to extend into the drift layer 102. The gate trench (GT) may completely penetrate the well region 105, and the bottom of the gate trench (GT) may be located within the drift layer 102. However, the depth at which the gate trench (GT) extends into the drift layer 102 may be varied in example embodiments. For example, in some example embodiments, the bottom of the gate trench (GT) may be located on the upper surface of the drift layer 102. A gate insulating layer 120 and a gate electrode 130 may be disposed within the gate trench (GT).

In some example embodiments, a field relief layer formed by doping a portion of the drift layer 102 along a portion of the outer surface of the gate trench (GT) may be further disposed. The field relief layer may be located within the drift layer 102 and may extend along the bottom surface of the gate trench (GT). The field relief layer may be a region having the same conductivity type as the well region 105, for example, the second conductivity type, and may include second conductivity type impurities.

The gate insulating layer 120 may be disposed on the sidewall and bottom surface of the gate trench (GT). The gate insulating layer 120 may have a non-uniform thickness. The gate insulating layer 120 may have a first thickness on the bottom surface of the gate trench (GT) and a second thickness on the sidewall of the gate trench (GT) and greater than the first thickness. The gate insulating layer 120 may include a region in which the thickness in the Z-direction gradually decreases from the center of the gate trench (GT) toward both sides thereof, below the gate electrode 130. The gate insulating layer 120 has a relatively large thickness on the bottom surface of the gate trench (GT), thereby mitigating an electric field formed in the drift layer 102 by the gate electrode 130, and thus reducing or preventing the destruction of the gate insulating layer 120. However, in example embodiments, the shape of the lower region of the gate trench (GT), the shape and thickness of the gate insulating layer 120 corresponding to the shape of the lower region of the gate trench (GT), and/or the like may be variously changed.

The gate electrode 130 may be disposed on the gate insulating layer 120 within the gate trench (GT). The gate electrode 130 may overlap the drift layer 102, the well region 105, and the source region 107 in the horizontal direction, for example, the Y-direction. The lower surface of the gate electrode 130 may be located within the drift layer 102. The lower surface of the gate electrode 130 may be positioned at a lower level than the lower surface of the well region 105, and the upper surface of the gate electrode 130 may be positioned at a lower level than the upper surface of the source region 107. However, in some example embodiments, the level of the upper surface of the gate electrode 130 may be positioned at the same level as or higher than the upper surface of the source region 107.

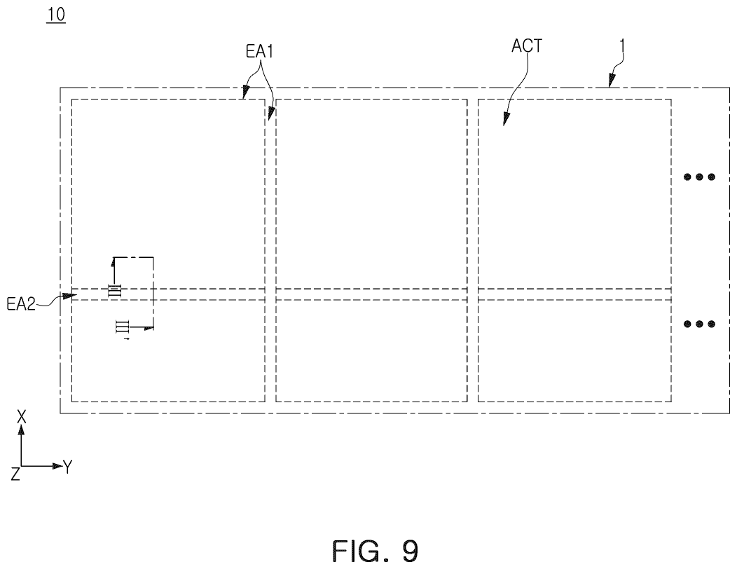

Hereinafter, a method for manufacturing the semiconductor devices of FIGS. 2 and 3 will be described with reference to FIGS. 9 to 12.

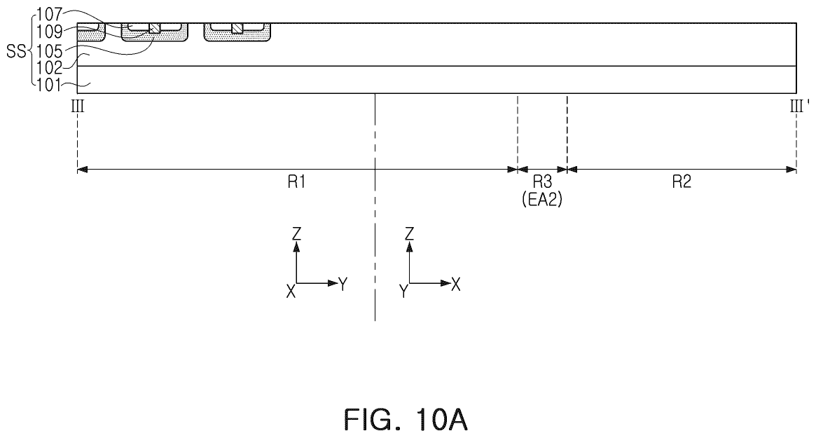

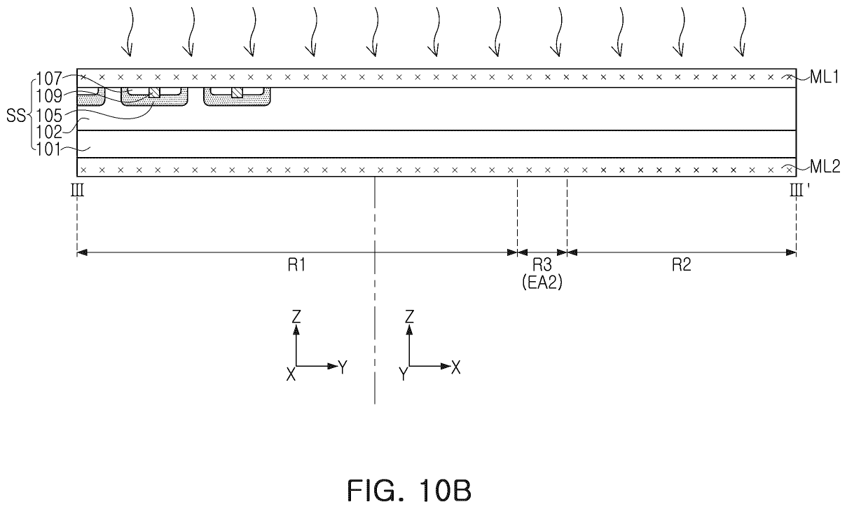

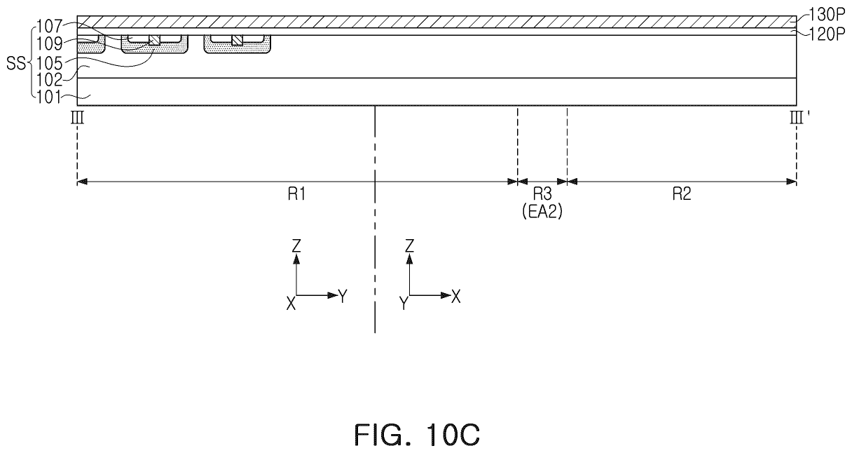

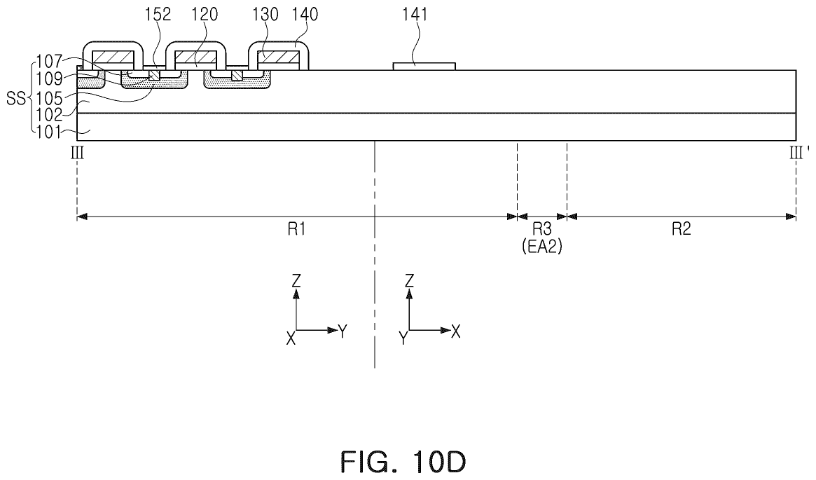

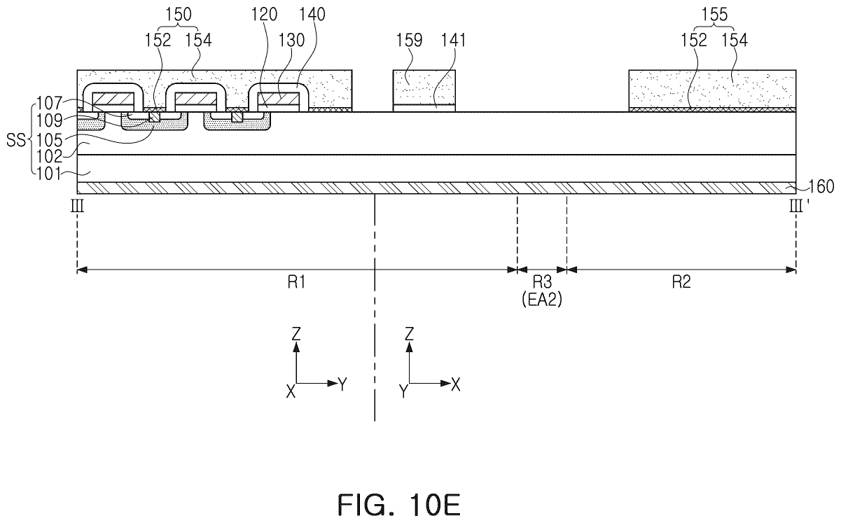

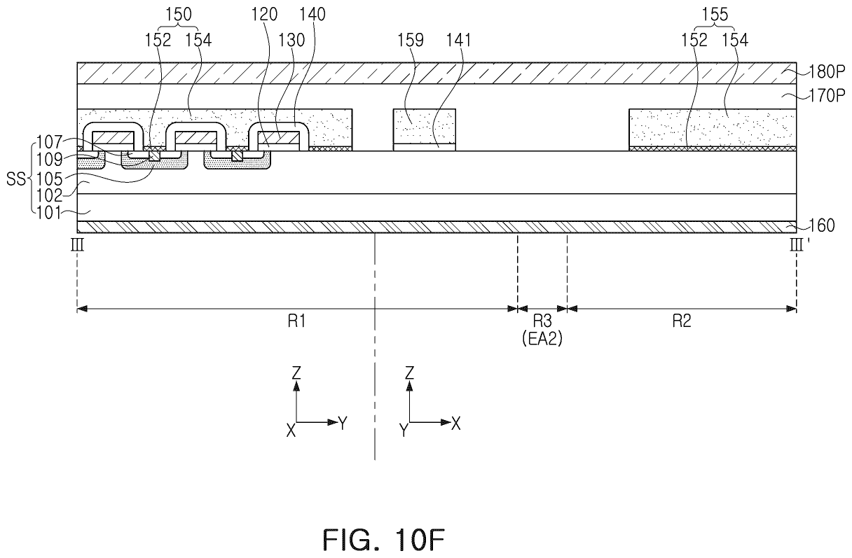

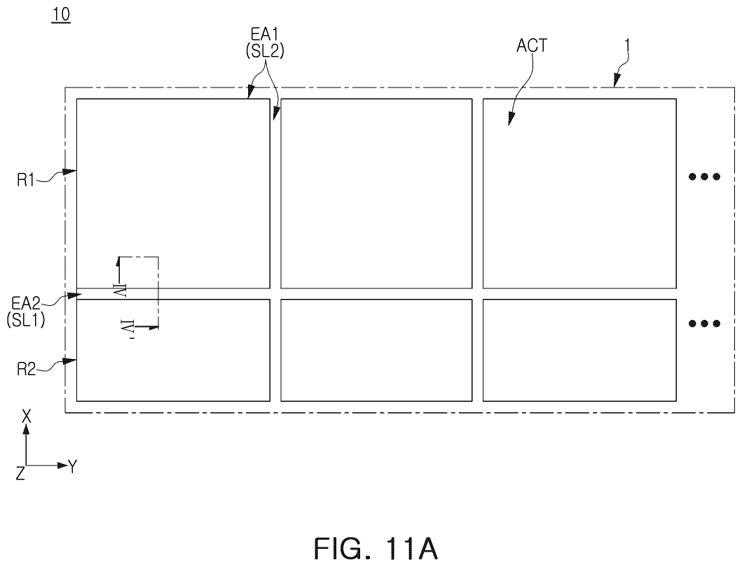

FIGS. 9, 11a, and 12 are top views of regions corresponding to the semiconductor devices 10 disposed within a wafer, FIGS. 10A to 10F are cross-sectional views of the semiconductor device of FIG. 9 taken along the cutting line III-III′, and FIG. 11B is a cross-sectional view of the semiconductor device of FIG. 11a taken along the cutting line IV-IV′.

FIG. 9 illustrates a region division for simultaneously forming a plurality of semiconductor devices 10 within a semiconductor substrate, for example, a SiC semiconductor wafer 1, and FIG. 9 illustrates a part of the semiconductor wafer 1.

The semiconductor wafer 1 includes a front surface and a back surface opposing each other, and a plurality of active regions (ACT) and peripheral regions EA1 between the active regions (ACT) may be defined on the front surface. The active regions (ACT) may have a quadrangular shape, for example, a rectangular shape, as illustrated in FIG. 9, but is not limited thereto. When an active region (ACT) is partitioned into rectangles, the active region may include a long side in the X-direction and a short side in the Y-direction. At this time, the long side may be longer than the short side, but may be shorter than twice the short side.

When the active regions (ACT) are arranged in a checkerboard shape, the peripheral regions EA1 may be disposed in a grid shape therebetween. Each semiconductor device 100 may be formed within each active region (ACT), and the peripheral regions EA1 may correspond to peripheral scribe lanes SL2 for cutting into respective semiconductor devices 100, but are not limited thereto.

Each active region (ACT) may include a first region R1, a second region R2, and internal peripheral regions EA2 corresponding to the scribe lanes SL1 between the first region R1 and the second region R2, as illustrated in FIGS. 2 and 3. The internal peripheral region EA2 may intersect with the peripheral region EA1, but is not limited thereto.

FIGS. 10A to 10F are cross-sectional views taken along line III-III′ of a unit semiconductor device 100 within respective active regions (ACT), and sequentially illustrate the first region R1, the third region R3 which is the internal peripheral region EA2, and the second region R2. FIGS. 10A to 10F illustrate a manufacturing method for manufacturing the semiconductor device 100 of FIG. 3 according to an example embodiment, and illustrate regions corresponding to respective regions in FIG. 3.

Referring to FIG. 10A, within a first region R1 of each active region (ACT), a substrate structure (SS) may be formed by forming a drift layer 102 on a substrate 101 and forming a well region 105, source regions 107 and well contact regions 109.

The substrate 101 may be provided as, for example, a SiC wafer 1. The drift layer 102 may be formed by epitaxial growth from the substrate 101. The drift layer 102 may be formed to include first conductivity-type impurities. The well region 105, source regions 107, and well contact regions 109 may be sequentially formed within the drift layer 102 by an ion implantation process. Second conductivity type impurities may be injected into the well region 105 and well contact regions 109, and first conductivity type impurities may be injected into the source regions 107. At this time, a drift layer 102 may be grown and formed in the second region R2, but a well region may not be formed. However, as illustrated in FIGS. 4 to 7, when the junction barrier regions 110 are formed, the second conductivity type impurities may be injected and formed according to a desired shape.

Referring to FIG. 10B, an annealing process may be performed.

The annealing process may be performed on the entire substrate structure (SS). Before the annealing process, first and second mask layers ML1 and ML2 may be formed on the front and back surfaces of the substrate structure (SS), respectively. The first and second mask layers ML1 and ML2 may reduce or prevent silicon (Si) of the substrate structure (SS) from melting during the annealing process. The first and second mask layers ML1 and ML2 may be, for example, photoresist layers.

The annealing process may be performed at a high temperature, for example, about 1600° C. to about 1800° C., and at a pressure of about 0.6 atm to about 1 atm. The annealing process may be performed, for example, in an argon (Ar) atmosphere. The ions injected by the ion injection process described above may be activated by the annealing process, and the substrate structure (SS) of the first region R1 and the second region R2 may be cured.

Referring to FIG. 10C, a preliminary gate insulating layer 120P and a preliminary gate electrode layer 130P may be formed on the entire surface of the substrate structure (SS).

The preliminary gate insulating layer 120P may be formed on the upper surfaces of the drift layer 102, the well regions 105, the source regions 107, and the well contact regions 109. The preliminary gate insulating layer 120P may be formed by a deposition process or an oxidation process, such as a thermal oxidation process.

The preliminary gate electrode layer 130P may be formed on the preliminary gate insulating layer 120P. The preliminary gate electrode layer 130P may be formed by depositing, for example, doped polycrystalline silicon on the preliminary gate insulating layer 120P. In some example embodiments, the preliminary gate electrode layer 130P may be formed of or include a metal material.

Referring to FIG. 10D, the gate insulating layers 120 and the gate electrode layers 130 may be formed, and the dielectric layers 140 may be formed.

The gate insulating layers 120 and the gate electrode layers 130 may be formed by patterning the laminated structure of the preliminary gate insulating layer 120P and the preliminary gate electrode layer 130P. Thus, respective portions of the source regions 107 and the well contact regions 109 may be exposed between gate structures (each comprising a gate insulating layer 120 and a corresponding gate electrode layer 130).

The dielectric layers 140 may be formed by forming a dielectric layer over the entire upper surface of the structure being manufactured, and then partially removing the dielectric layer by an etching process to expose respective portions of the source regions 107, the well contact regions 109, and the second element region. The dielectric layer 140 may be formed to cover the upper surface and side surface of the gate electrode 130, the side surface of the gate insulating layer 120, and a portion of the upper surface of the source region 107. In addition, a portion of the dielectric layers 140 may remain and be disposed below the gate bus line 159 and the gate bus pad 157 to form a bus insulating layer 141.

Referring to FIG. 10E, a source electrode 150, a gate bus line 159, and a metal layer 155 may be formed on the first region R1 and the second region R2.

First, metal-semiconductor compound layers 152 may be formed at the interface with the source regions 107, the well contact regions 109, and the drift layer 102 of the second element region R2a. The metal-semiconductor compound layers 152 may be formed, for example, by a silicidation process. The conductive layer 154 may be formed to cover the metal-semiconductor compound layers 152 and the dielectric layers 140 in the first region R1, and may be formed to cover the region excluding the second edge region R2b in the second region R2. By this, the source electrode 150, the gate bus line 159, and the metal layer 155 of the second element region R2a may be formed, respectively. The gate bus line 159 may simultaneously contact the plurality of gate electrodes 130 from the lower portion thereof. The source electrode 150, the gate bus line 159, and the metal layer 155 may have a flat upper surface or a curved upper surface by a planarization process.

Meanwhile, the back electrode 160 may be formed on the back surface of the substrate 101. In some example embodiments, the back electrode 160 may be formed in another process step. The back electrode 160 may function as a drain electrode in the first region R1 and as a cathode electrode that applies a cathode voltage in the second region R2. A back grinding process for the substrate 101 may be further performed before the formation of the back electrode 160. The back electrode 160 may be formed only in the active region (ACT) and may not be formed in the peripheral region EA1. However, the back electrode 160 may be continuously disposed in the region vertically overlapping the internal peripheral region EA2 to connect the first region R1 and the second region R2.

Referring to FIG. 10f, a preliminary first passivation layer 170P and a preliminary second passivation layer 180P may be formed.

The preliminary first passivation layer 170P may be formed to cover all of the upper surfaces of the source electrode 150, the gate bus line 159, the metal layer 155, and the upper surface of the exposed substrate structure (SS). Therefore, the preliminary first passivation layer 170P may be disposed in the space between the spaced-apart source electrode 150, the gate bus line 159, and the metal layer 155. The preliminary first passivation layer 170P may be formed by depositing an insulating material.

The preliminary second passivation layer 180P may be formed on the preliminary first passivation layer 170P. The upper surface of the preliminary first passivation layer 170P may be flat, and the upper surface of the preliminary second passivation layer 180P may also be flat.

Referring to FIGS. 11A and 11B, scribe lanes SL1 and SL2 may be formed in the peripheral regions EA1 and EA2. The scribe lanes SL1 and SL2 may be formed within the peripheral regions EA1 and EA2 surrounding each active region (ACT), and may be formed to have a width equal to or smaller than a width of the peripheral regions EA1 and EA2.

In addition, a portion of the scribe lanes SL1 and SL2 may be formed to extend in the X-direction in the internal peripheral region EA2 between the first region R1 and the second region R2, within the active regions (ACT). The remaining (SL2) of the scribe lanes SL1 and SL2 may be formed as peripheral scribe lanes SL2 in a lattice shape between the active regions (ACT). The scribe lanes SL2 may extend to each other between the adjacent active regions (ACT). As illustrated in FIG. 11B, the scribe lanes SL1 and SL2 may form a recessed region extending from the upper surface of the preliminary second passivation layer 180 to the upper surface of the drift layer 101 of the substrate structure (SS). The scribe lanes SL1 and SL2 may be formed through laser grooving, but are not limited thereto.

By the scribe lane SL1, a recessed region is formed between the first region R1 and the second region R2, so that two different types of circuit elements may be defined, and the substrate 101 may be shared between the two circuit elements without cutting the substrate 101. However, the scribe lanes SL1 and SL2 are not removed to the upper surface of the substrate 101, but may be formed by sinking into at least a part of the preliminary first passivation layer 170P, but are not limited thereto. By the laser grooving, both sides of the scribe lanes SL1 and SL2 may have an inclined side surface (e.g., a slope), but are not limited thereto, and may be formed perpendicular to the front surface of the substrate 101.

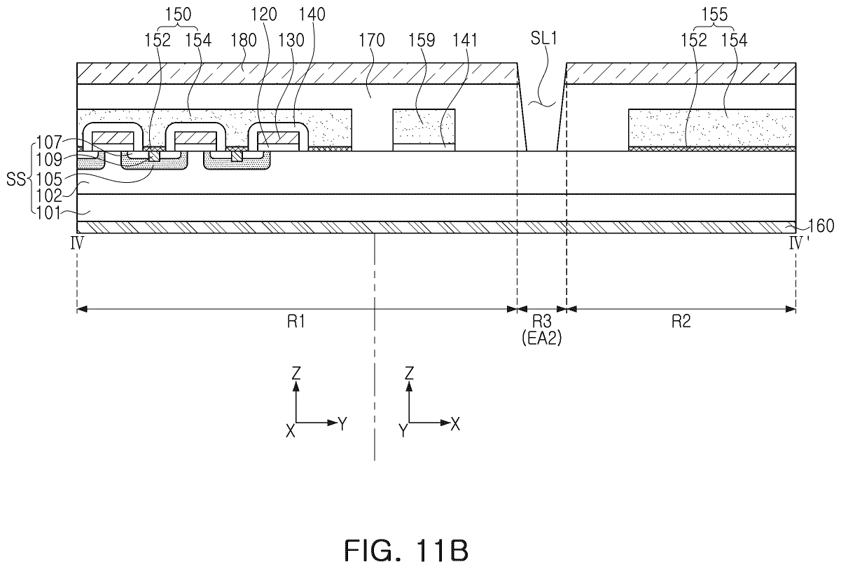

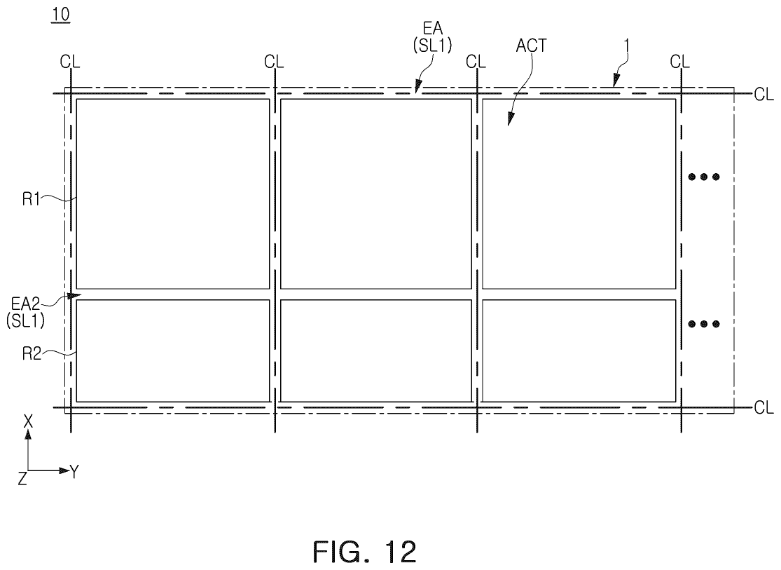

Next, as illustrated in FIG. 12, semiconductor devices 100 disposed in respective active regions (ACT) may be cut along a cutting line (CL) to form unit semiconductor devices 100. The cutting line (CL) may be formed to pass through the center of the width of peripheral regions EA1 between the active regions (ACT), but the present inventive concepts are not limited thereto. In addition, the cutting line (CL) is formed to cut only the substrate 101 while passing through the center of the peripheral scribe lane SL2 formed in the peripheral regions EA1, and thus, separation into unit semiconductor devices 100 may be performed.

However, the scribe lane SL1 within a single active region (ACT) may be cut and form the structure of FIGS. 2 and 3, which includes a first region R1, a second region R2, and a third region R3 (e.g., a scribe lane SL1) therebetween within a unit semiconductor device 100.

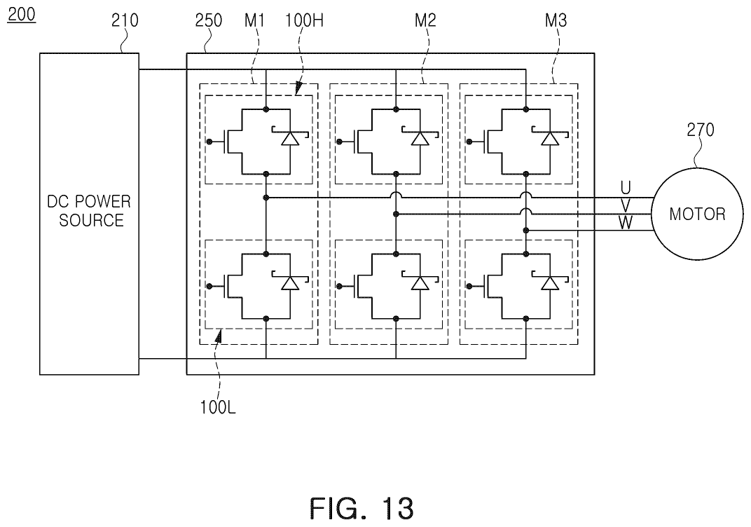

Hereinafter, a power unit to which a semiconductor device according to an example embodiment is applied will be described with reference to FIGS. 13 to 15.

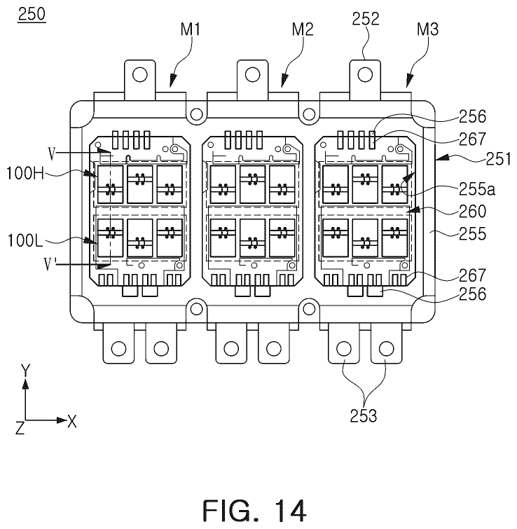

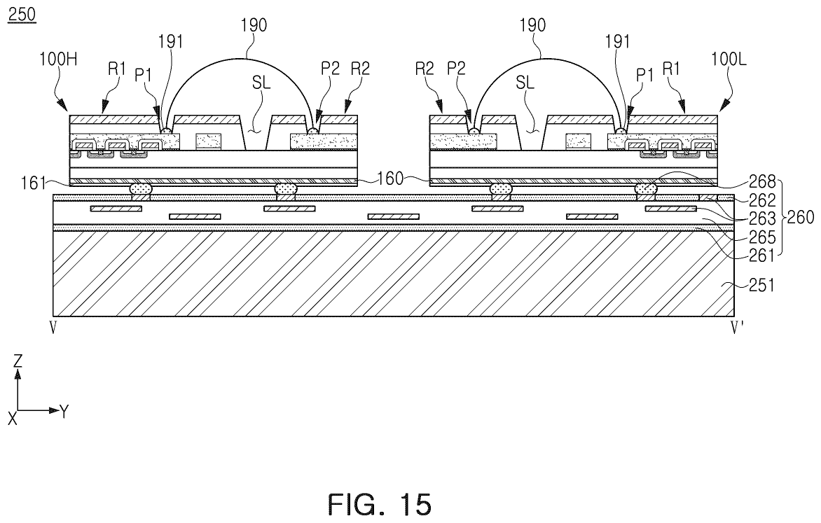

FIG. 13 is a circuit diagram illustrating a power unit 250 to which a power semiconductor device according to an example embodiment is applied, FIG. 14 is a configuration diagram illustrating an inverter module of FIG. 13, and FIG. 15 is a cross-sectional view of the inverter module of FIG. 14 taken along line V-V′.

As illustrated in FIG. 13, a power unit 200 driving a motor 270 may include an inverter 250 that converts the DC power 210 into AC power (U, V, W) for driving the motor.

The inverter 250 may include three inverter circuit units M1, M2 and M3 connected between a high voltage node and a low voltage node, applied from the DC power 210, in parallel.

Respective inverter circuit units M1, M2 and M3 have the same configuration, and a first output unit 100H and a second output unit 100L are connected in series between the high voltage node and the low voltage node.

The AC power (U, V, W) may be transmitted to the motor 270, between the first output unit 100H and the second output unit 100L.

The first output unit 100H and the second output unit 100L include the same circuit elements, and may include one transistor (TR) and one diode (SBD). The drain of the transistor (TR) of the first output unit 100H and the cathode of the diode (SBD) may be simultaneously connected to a high voltage node, and the source of the transistor (TR) and the anode of the diode (SBD) may be simultaneously connected to the output nodes nu, nv, and nw.

The drain of the transistor (TR) of the second output unit 100L and the cathode of the diode (SBD) may be simultaneously connected to the output nodes nu, nv and nw, and the source of the transistor (TR) and the anode of the diode (SBD) may be simultaneously connected to the low voltage node.

Accordingly, the transistors (TR) of the first output unit 100H and the second output unit 100L may be selectively turned on according to the gate signal of the gate to transmit the voltage of the high voltage node or the low voltage node to the output nodes nu, nv, and nw. At this time, the diode (SBD) is connected in the reverse direction so that the transistor (TR) is turned off during normal operation, and when the transistors (TR) are turned off, the diode (SBD) is turned on by the counter electromotive force from the motor, so that current may flow through the diode (SBD). The inverter circuit units M1, M2 and M3 like this are turned on at different times to generate three-phase AC power (U, V, W), so that the three-phase AC power (U, V, W) may be applied to the motor 270.

In this case, each of the first output unit 100H and the second output unit 100L of respective inverter circuit units M1, M2 and M3 may be a semiconductor device 100, and may be a semiconductor device 100 according to the example embodiment of FIGS. 2 and 3, and the inverter circuit units M1, M2 and M3 may have a configuration like the inverter module of FIGS. 14 and 15.

Referring to FIGS. 14 and 15, the inverter module 250 may include a housing 251, circuit boards 260 mounted in the housing 251 and corresponding to respective inverter circuit units M1, M2 and M3, and semiconductor devices 100H and 100L mounted on the circuit board 260.

The housing 251 may include an insulating material, include a receiving portion 255a that receives the circuit board 260 therein, and include a body 255 having a shape similar to the shape of the circuit board 260. The body 255 may have a desired (or alternatively, predetermined) thickness and include fastening holes that may be fastened to an external device. The fastening holes may be disposed on the outside of the receiving portion 255a of the body 255 and may be disposed in a surplus space.

The housing 251 may include external terminals 252 and 253 protruding outward from the outer surface of the body 251, and the external terminals 252 and 253 may be disposed on the upper and lower sides of the body 251, and may be disposed to have various numbers. At this time, the number of upper external terminals 252 and lower external terminals 253 may not be the same, but is not limited thereto.

The housing 251 includes internal terminals 256 for electrical connection with the circuit board 260, and the internal terminals 256 may protrude from each side of the receiving portion 255a in which the circuit board 260 is received. At this time, the internal terminals 256 may be implemented as spring terminals so that physical connection and electrical connection between the circuit board 260 and the housing 251 are implemented simultaneously, but are not limited thereto.

The housing 251 may be integrated with three inverter circuit units M1, M2 and M3, but is not limited thereto, and examples of the housing may include a plurality of housings 251 separated from each other for respective inverter circuit units M1, M2 and M3. A circuit board 260 is accommodated in each of the receiving portions 255a of the housing 251. The circuit board 260 may be a printed circuit board, and may be connected to internal terminals 256 of the housing 251 to receive input power and transmit output power. The circuit board 260 includes at least one layer of circuit patterns 263 patterned in an insulating substrate 265, as illustrated in FIG. 15, and passivation layers 261 and 262 may be disposed on the upper and lower surfaces of the insulating substrate 265, respectively.

In FIG. 15, the lower surface of the circuit board 260 is illustrated as being in contact with the bottom surface of the receiving portion 255a of the housing 251, but is not limited thereto, and the lower surface of the circuit board 260 may be disposed to be spaced apart therefrom by a desired (or alternatively, predetermined) distance.

A portion of the upper passivation layer 262 of the circuit board 260 is exposed to form upper pads 263, which are part of the circuit patterns 263, and semiconductor devices 100H and 100L may be mounted by solder balls 268 in contact with the upper pads 263. The back electrodes 160 of the semiconductor devices 100H and 100L may be covered by the back protection layer 161, and a portion thereof may be opened to be connected to the circuit board 260 by solder balls 268.

At least two rows of semiconductor devices 100H and 100L may be disposed on each circuit board 260, and the semiconductor devices 100H in one row may represent a first output unit 100H in FIG. 13, and the semiconductor devices 100L in the second row may represent a second output unit 100L in FIG. 13. The same semiconductor devices 100H and 100L may be connected in parallel through the circuit pattern 263 of the circuit board 260 to operate simultaneously to improve the inverter performance, but this is not limited thereto, and the semiconductor devices 100H and 100L corresponding to the first output unit 100H and the second output unit 100L may be respectively assigned as one.

The semiconductor devices 100H and 100L of the first and second rows may be disposed with a desired (or alternatively, predetermined) distance apart from each other, and the semiconductor devices 100H and 100L of the first and second rows may be disposed as mirror images of each other. For example, the second regions R2 may be disposed to face each other, and the first regions R1 may be disposed to face each other. In addition, when a plurality of semiconductor devices 100H and 100L are disposed in one row, they may be disposed in reverse order so that the second region R2 is disposed adjacent to the first region R1.

As illustrated in FIG. 15, the upper surfaces of respective semiconductor devices 100H and 100L, for example, the second passivation layer 180 and the second passivation layer 170, may be partially removed to form upper pad regions P1 and P2.

The upper pad regions P1 and P2 may include first pad regions P1 that expose source electrodes 150 of the first region R1 and second pad regions P2 that expose the metal layer 155 of the second region R2.

In a semiconductor device 100, a plurality of upper pad regions P1 and P2 may be disposed, and a wire 190, which is a connecting member for electrically connecting a source electrode 150 of a first region R1 and a metal layer 155 of a second region R2 through the corresponding upper pad regions P1 and P2, may be disposed.

A plurality of wires 190 may be disposed in a single semiconductor device 100, and although FIG. 14 illustrates that two wires 190 are disposed, the present inventive concepts are not limited thereto, and a relatively greater number of wires 190 may be allocated. Solders 191 may be disposed to connect both ends of the wire 190 and respective electrodes 150 and 155.

In this manner, the semiconductor device according to an example embodiment is formed so that the SiC transistor (TR) and the Schottky barrier diode (SBD) share the substrate 101 in the inverter, and by including the scribe lane SL1 between the two elements, the Schottky barrier diode (SBD) may be formed together with the transistor (TR) on one semiconductor substrate 101 without manufacturing it as a separate semiconductor chip, thereby configuring it as one chip. In addition, in some semiconductor devices 101, the scribe lane SL1 between the transistor (TR) and the diode (SBD) may be cut so that only the transistor (TR) element or the diode (SBD) element may be utilized.

When applied to an inverter, which is a power unit 250 including both a transistor (TR) and a diode (SBD), the heat of the transistor (TR) with high heat generation may be shared with the diode (SBD) with low heat generation, so that the area of the substrate 101 on the diode (SBD) side may also be utilized for heat dissipation, so that the heat dissipation efficiency may be significantly improved.

As set forth above, by designing a semiconductor device including both a transistor region and a Schottky barrier diode region within a SiC substrate, heat dissipation efficiency may be improved because heat from a high-heat transistor may be dissipated by sharing the SiC substrate of the diode.

While some example embodiments have been illustrated and described above, it will be apparent to those skilled in the art that modifications and variations could be made without departing from the scope of the present inventive concepts as defined by the appended claims.

What is claimed is:

1. A power semiconductor device comprising:
a substrate including SiC of a first conductivity type, the substrate including a first region and a second region;
a drift layer of the first conductivity type on the substrate, the drift layer being in the first region and the second region;
a well region of a second conductivity type on the drift layer, the well region being in the first region;
a source region of the first conductivity type within the well region;
a gate electrode on and extending along an upper surface of the well region;
a source electrode connected to the source region in the first region;
a metal layer connected to the drift layer in the second region; and
a passivation layer covering the source electrode and the metal layer,
wherein the passivation layer defines a recessed portion between the first region and the second region.

2. The power semiconductor device of claim 1, wherein the first region includes a first type circuit element, and the second region includes a second type circuit element different from the first type circuit element.

3. The power semiconductor device of claim 2, wherein the first type circuit element includes a transistor, and the second type circuit element includes a Schottky barrier diode.

4. The power semiconductor device of claim 2, wherein
the first region includes a first element region and a first edge region, the first element region including the first type circuit element therein, the first edge region being between the first element region and the recessed portion, and
the second region includes a second element region and a second edge region, the second element region including the second type circuit element therein, the second edge region being, between the second element region and the recessed portion.

5. The power semiconductor device of claim 4, wherein the source electrode is in the first element region, the metal layer is in the second element region, and the passivation layer is in contact with an upper surface of the drift layer in the first edge region and the second edge region.

6. The power semiconductor device of claim 4, wherein
when viewed in a plan view, the recessed portion has a line shape crossing between the first region and the second region, and
a width of the recessed portion is equal to or smaller than a width of the first edge region and/or a width of the second edge region.

7. The power semiconductor device of claim 1, wherein
a first side surface of the first region and a second side surface of the second region defined by the recessed portion face each other, and
the first side surface and the second side surface have slopes.

8. The power semiconductor device of claim 1, wherein the source electrode and the metal layer include a same metal material.

9. The power semiconductor device of claim 1, wherein
the power semiconductor device includes a first pad region exposing at least a portion of the source electrode from an upper surface of the passivation layer and a second pad region exposing at least a portion of the metal layer from the upper surface of the passivation layer, and
the power semiconductor device further includes a wire between the first pad region and the second pad region.

10. The power semiconductor device of claim 1, further comprising:
a plurality of junction barrier regions in the second region, the plurality of junction barrier regions spaced apart from each other in an upper portion of the drift layer.

11. The power semiconductor device of claim 10, wherein the plurality of junction barrier regions have a polygonal frame shape.

12. The power semiconductor device of claim 1, wherein the first conductivity type is an N-type, and the second conductivity type is a P-type.

13. A power semiconductor device comprising:
a first region including a transistor;
a second region spaced apart from the first region, the second region including a Schottky barrier diode;
a passivation layer on the first region and the second region; and
a third region between the first region and the second region, the third region being a region in which at least a portion of the passivation layer is removed,
wherein the first region includes,
a first SiC substrate of a first conductivity type,
a well region of a second conductivity type on the first SiC substrate,
a source region of the first conductivity type within the well region,
a gate electrode on an upper surface of the well region, and
a source electrode connected to the source region, and
the second region includes,
a second SiC substrate of the first conductivity type, and
an electrode layer connected to the second SiC substrate, and
wherein the first SiC substrate and the second SiC substrate are respective parts of an integral body.

14. The power semiconductor device of claim 13, wherein an area of the first region is larger than an area of the second region.

15. The power semiconductor device of claim 13, wherein
when viewed in a plan view, the first region and the second region have a same width in a first direction, and
a length of the first region is greater than a length of the second region in a second direction perpendicular to the first direction.

16. The power semiconductor device of claim 15, wherein when viewed in a plan view, the third region has a line shape having a same width as the first region in the first direction.

17. The power semiconductor device of claim 13, wherein the first SiC substrate and the second SiC substrate are respective parts of the integral body, and a portion of the integral body are exposed in the third region.

18. The power semiconductor device of claim 13, wherein
the source electrode of the first region has a first separation distance from the third region, and an electrode layer of the second region has a second separation distance from the third region, and
the first separation distance is substantially equal to the second separation distance.

19. A power semiconductor device comprising:
a substrate including SiC of a first conductivity type, the substrate including a first region and a second region;
a well region of a second conductivity type on the substrate, the well region being in the first region;
a source region of the first conductivity type within the well region;
a gate electrode on and extending along an upper surface of the well region;
a source electrode connected to the source region in the first region;
a metal layer connected to the substrate in the second region;
a passivation layer covering the source electrode and the metal layer, the passivation layer including a first pad region and a second pad region, the first pad region exposing at least a portion of the source electrode, the second pad region exposing at least a portion of the metal layer; and
a connecting member electrically connecting the source electrode exposed in the first pad region and the metal layer exposed the second pad region,
wherein the passivation layer defines a recessed portion between the first region and the second region, and the recessed portion defines a scribe lane.

20. The power semiconductor device of claim 19, wherein the connecting member electrically connects a transistor of the first region and a Schottky barrier diode of the second region.
